(19) United States
(12) Patent Application Publication
(10) Pub. No.: US 2024/0348219 A1
(43) Pub. Date: Oct. 17, 2024

(54) DIFFERENTIAL AMPLIFICATION DEVICE AND COMPENSATION METHOD THEREOF

(71) Applicant: VIA LABS, INC., New Taipei City (TW)

(72) Inventors: Hsiao-Chyi Lin, New Taipei City (TW); Yi-Shing Lin, New Taipei City (TW)

(73) Assignee: VIA LABS, INC., New Taipei City (TW)

(21) Appl. No.: 18/604,506

(22) Filed: Mar. 14, 2024

Related U.S. Application Data
(60) Provisional application No. 63/458,908, filed on Apr. 12, 2023.

(30) Foreign Application Priority Data
Oct. 27, 2023 (TW) 112141383

(51) Int. Cl. H03F 3/45

(52) U.S. Cl. CPC H03F 3/45475

(57) ABSTRACT

A differential amplification device and a compensation method thereof. The differential amplification device includes a first terminal signal circuit, a second terminal signal circuit and a controller. The first terminal signal circuit and the second terminal signal circuit respectively generate a first terminal signal and a second terminal signal of a differential output signal to a first terminal of a transmission path. The controller adjusts first element parameters of the first terminal signal circuit or second element parameters of the second terminal signal circuit based on a transmitted differential signal at a second terminal of the transmission path to compensate for asymmetric influence by the transmission path on the first terminal signal and the second terminal signal of the transmitted differential signal. Adjustment of the first element parameter of the first terminal signal circuit is independent of adjustment of the second element parameter of the second terminal signal circuit.

### CROSS-REFERENCE TO RELATED APPLICATION

This application claims the priority benefits of U.S. provisional application Ser. No. 63/458,908, filed on Apr. 12, 2023, and Taiwan application serial no. 112141383, filed on Oct. 27, 2023. The entirety of each of the above-mentioned patent applications is hereby incorporated by reference herein and made a part of this specification.

### BACKGROUND

### Technical Field

The disclosure relates to an electronic circuit, and in particular to a differential amplification device and a compensation method thereof.

### Description of Related Art

A differential output signal of a transmission device is transmitted to a receiving device through a transmission path. For example, the differential output signal of the transmission device is transmitted to a Universal Serial Bus (USB) receiving device through an integrated circuit package, a printed circuit board (PCB), a USB connector and a USB cable. Generally speaking, non-ideal effects of a transmission path affect a differential signal, causing symmetry differences in the differential signal received by a receiving device from the transmission path (a transmitted differential signal). For example, asymmetric influence by the transmission path on a first terminal signal and a second terminal signal of the transmitted differential signal may include: the attenuation of the first terminal signal of the transmitted differential signal by the transmission path is different from the attenuation of the second terminal signal of the transmitted differential signal by the transmission path. Based on this, a common mode voltage of the transmitted differential signal received by the receiving device is far away from a rated common mode voltage level (for example, 0 V). For the USB Fourth Edition (USB4) specification, it is unacceptable for the common mode voltage of the transmitted differential signal to be far from the rated common mode voltage level.

### SUMMARY

The disclosure provides a differential amplification device and a compensation method thereof to compensate for the asymmetric influence by a transmission path on a first terminal signal and a second terminal signal in a transmitted differential signal.

In an embodiment of the disclosure, the above-mentioned differential amplification device is configured to generate a differential output signal to a first terminal of the transmission path. The differential amplification device includes a first terminal signal circuit, a second terminal signal circuit and a controller. The first terminal signal circuit generates a first terminal signal in the differential output signal. The second terminal signal circuit is coupled to the first terminal signal circuit. The second terminal signal circuit generates a second terminal signal in the differential output signal. The controller is coupled to the first terminal signal circuit and the second terminal signal circuit. The controller adjusts at least one first element parameter of the first terminal signal circuit or at least one second element parameter of the second terminal signal circuit based on a transmitted differential signal at a second terminal of the transmission path to compensate for the asymmetric influence by the transmission path on a first terminal signal and a second terminal signal in the transmitted differential signal. The adjustment of the at least one first element parameter of the first terminal signal circuit is independent of the adjustment of the at least one second element parameter of the second terminal signal circuit.

In an embodiment of the disclosure, the above-mentioned compensation method is configured to compensate for the asymmetric influence by a transmission path on a first terminal signal and a second terminal signal in a transmitted differential signal. The compensation method includes: A first terminal signal in a differential output signal is generated by a first terminal signal circuit to a first terminal of a transmission path; a second terminal signal in the differential output signal is generated by a second terminal signal circuit to the first terminal of the transmission path, and the second terminal signal circuit is coupled to the first terminal signal circuit; and at least one first element parameter of the first terminal signal circuit or at least one second element parameter of the second terminal signal circuit is adjusted based on the transmitted differential signal at a second terminal of the transmission path to compensate for the asymmetric influence by the transmission path on the first terminal signal and the second terminal signal of the transmitted differential signal, and the adjustment of the at least one first element parameter of the first terminal signal circuit is independent of the adjustment of the at least one second element parameter of the second terminal signal circuit.

Based on the above, the controller in the embodiments of the disclosure may adjust the element parameters of the first terminal signal circuit independently of the adjustment of the element parameters of the second terminal signal circuit, that is, the adjustment of the first terminal signal in the differential output signal may be independent of the adjustment of the second terminal signal in the differential output signal. In general, the transmission path may have the asymmetric influence on the transmitted differential signal. For example, the attenuation degree of the first terminal signal of the transmitted differential signal by the transmission path is different from the attenuation degree of the second terminal signal of the transmitted differential signal by the transmission path. Due to the asymmetric influence by the transmission path on the transmitted differential signal, the common mode voltage of the transmitted differential signal received by the receiving device may be far away from the rated common mode voltage level (such as 0 V or other target levels). Based on the transmitted differential signal of the transmission path, the controller may correspondingly adjust/set the element parameters of the first terminal signal circuit and/or the element parameters of the second terminal signal circuit. Because the adjustment of the element parameters of the first terminal signal circuit may be independent of the adjustment of the element parameters of the second terminal signal circuit, the differential amplification device may compensate for the asymmetric influence by the transmission path on the first terminal signal and the second terminal signal of the transmitted differential signal.

In order to make the aforementioned features and advantages of the disclosure comprehensible, embodiments accompanied with drawings are described in detail as follows.

### BRIEF DESCRIPTION OF THE DRAWINGS

FIG. 1 is a schematic circuit block diagram of an electronic device according to an embodiment of the disclosure.

FIG. 2 is a schematic circuit block diagram of a differential amplification device according to an embodiment of the disclosure.

FIG. 3 is a schematic flowchart of a compensation method according to an embodiment of the disclosure.

FIG. 4 is a schematic flowchart of a compensation method according to another embodiment of the disclosure.

FIG. 5 is a schematic circuit block diagram of the amplifier according to an embodiment of the disclosure.

FIG. 6 is a schematic circuit block diagram of the amplifier according to another embodiment of the disclosure.

FIG. 7 is a schematic circuit block diagram of the amplifier according to yet another embodiment of the disclosure.

### DESCRIPTION OF THE EMBODIMENTS

The term “coupled (or connected)” used in the specification (including the claims) may refer to any direct or indirect means of connection. For example, if that a first device is coupled (or connected) to a second device is described in the specification, the description should be construed that the first device may be directly connected to the second device, or the first device may be indirectly connected to the second device through other devices or some kind of connection means. The terms “first,” “second” and the like mentioned in the specification (including the claims) are used to name the elements or to distinguish different embodiments or scopes and are not intended to limit the upper or lower limit of the number of the elements, nor are the terms intended to limit the order of the elements. In addition, wherever possible, elements/components/steps with the same reference numerals in the drawings and embodiments represent the same or similar parts. Elements/components/steps with the same reference numerals or with the same terminology in different embodiments may refer to relative descriptions of each other.

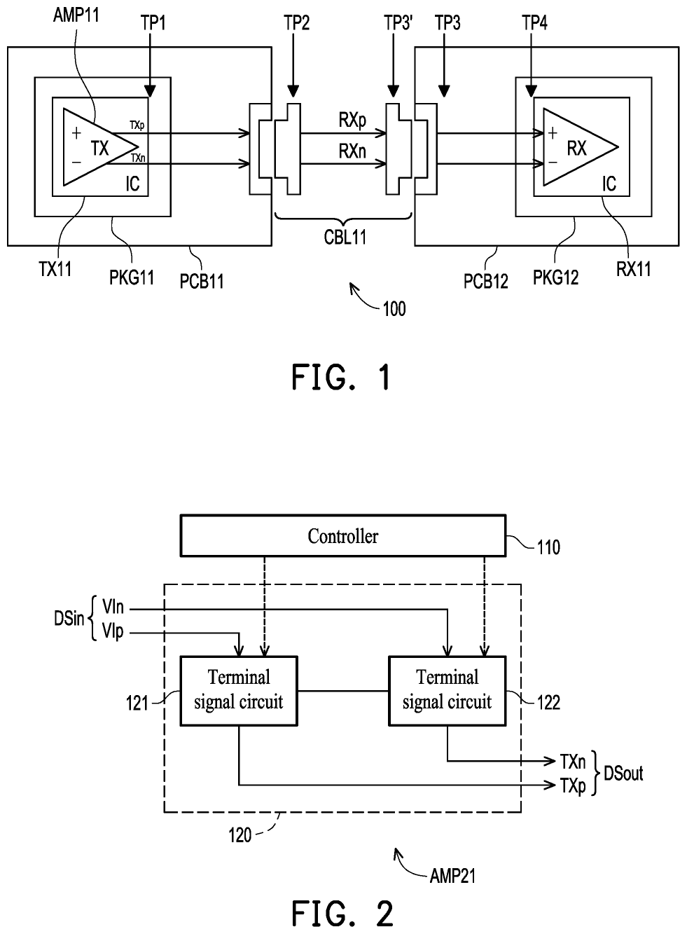

FIG. 1 is a schematic circuit block diagram of an electronic device 100 according to an embodiment of the disclosure. The electronic device 100 shown in FIG. 1 includes a transmission device TX11 and a receiving device RX11. The transmission device TX11 is disposed in an integrated circuit package PKG11, and the receiving device RX11 is disposed in an integrated circuit package PKG12. The integrated circuit package PKG11 is disposed on a printed circuit board (PCB) PCB11, and the integrated circuit package PKG12 is disposed on a printed circuit board PCB12. One terminal of a cable CBL11 is connected to a connector of the printed circuit board PCB11, and the other terminal of the cable CBL11 is connected to a connector of the printed circuit board PCB12. Based on actual design, the cable CBL11 may be a Universal Serial Bus (USB) cable or other cables.

A differential output signal (terminal signals TXp and TXn) of a differential amplification device AMP11 in the transmission device TX11 may be transmitted to the receiving device RX11 through the integrated circuit package PKG11, the printed circuit board PCB11, the cable CBL11, the printed circuit board PCB12 and the integrated circuit package PKG12. Usually, a common mode voltage of a differential signal at a test point TP1 may match a rated common mode voltage level (such as 0 V or other target levels, as determined by actual design). Generally speaking, a transmission path of the differential output signal has non-ideal effects. For example, the non-ideal effects may include discontinuity, mismatch, reflection, coupling and other effects. The non-ideal effects of the transmission path may cause a transmitted differential signal (terminal signals RXp and RXn) to generate common-mode noise, and the noise affects the receiving capability of the receiving device RX11. Therefore, the USB Fourth Edition (USB4) specifies that such noise needs to be less than 100 m Vpp.

Specifically, the non-ideal effects of the transmission path may have asymmetric influence on the transmitted differential signal (the terminal signals RXp and RXn). For example, an attenuation degree of the terminal signal RXp by the transmission path may be different from an attenuation degree of the terminal signal RXn by the transmission path. Due to the asymmetric influence by the transmission path on the transmitted differential signal, the common mode voltage of the transmitted differential signal received by the receiving device RX11 may drift away from the rated common mode voltage level (such as 0 V or other target levels, as determined by actual design). That is, the common mode voltages of the differential signals at test points TP2, TP3′, TP3 and/or TP4 may be far away from the rated common mode voltage level.

Based on the transmitted differential signal (the terminal signals RXp and RXn) of the transmission path, the differential amplification device AMP11 may independently adjust the terminal signals TXp and/or TXn of the differential output signal. For example, in response to the attenuation of the terminal signal RXp by the transmission path being greater than the attenuation of the terminal signal RXn by the transmission path, the differential amplification device AMP11 may increase the voltage level of the terminal signal TXp without adjusting the voltage level of the terminal signal TXn, or the differential amplification device AMP11 may lower the voltage level of the terminal signal TXn without adjusting the voltage level of the terminal signal TXp. Therefore, the differential amplification device AMP11 may compensate for the asymmetric influence by the transmission path on the terminal signals RXp and/or RXn of the transmitted differential signal. For another example, in response to the attenuation of the terminal signal RXp by the transmission path being less than the attenuation of the terminal signal RXn by the transmission path, the differential amplification device AMP11 may lower the voltage level of the terminal signal TXp without adjusting the voltage level of the terminal signal TXn, or the differential amplification device AMP11 may increase the voltage level of the terminal signal TXn without adjusting the voltage level of the terminal signal TXp. Because the adjustment of the terminal signal TXp may be independent of the adjustment of the terminal signal TXn, the differential amplification device AMP11 may compensate for the asymmetric influence by the transmission path on the transmitted differential signal. Therefore, the differential amplification device AMP11 may compensate for the common mode voltage at the transmission terminal of the USB4 high-speed circuit, thereby complying with the requirements of the USB4 specification.

FIG. 2 is a schematic circuit block diagram of a differential amplification device AMP21 according to an embodiment of the disclosure. For the differential amplification device AMP21 shown in FIG. 2, reference may be made to the relevant description of the differential amplification device AMP11 shown in FIG. 1 and analogies may be made. Based on terminal signals VIn and VIp of a differential input signal DSin, the differential amplification device AMP21 shown in FIG. 2 may generate a differential output signal DSout to a first terminal of a transmission path. Based on an actual test scenario, the transmission path may include a transmission path from the differential amplification device AMP11 shown in FIG. 1 (the differential amplification device AMP21 shown in FIG. 2) to any one of the test points TP1, TP2, TP3′, TP3 and TP4. In the embodiment shown in FIG. 2, the differential amplification device AMP21 includes a controller 110 and an amplifier 120. The amplifier 120 shown in FIG. 2 includes a terminal signal circuit 121 and a terminal signal circuit 122. The terminal signal circuit 122 is directly or indirectly coupled to the terminal signal circuit 121. Based on the control of the controller 110, the amplifier 120 may adjust the terminal signal TXn of the differential output signal DSout independently of the adjustment of the terminal signal TXp of the differential output signal DSout.

According to different design, in some embodiments, the controller 110 may be implemented as a hardware circuit. In other embodiments, the controller 110 may be implemented in the form of firmware, software (i.e., programs), or a combination of the foregoing. In some embodiments, the implementation of the controller 110 may be a combination of hardware, firmware and software.

In terms of hardware, the controller 110 may be implemented as a logic circuit on an integrated circuit. For example, the relevant functions of the controller 110 may be implemented in one or more controllers, microcontrollers, microprocessors, application-specific integrated circuits (ASICs), digital signal processors (DSPs), field programmable gate arrays (FPGAs), central processing units (CPUs) and/or various logic blocks, modules and circuits in other processing units. The relevant functions of the controller 110 may be implemented as hardware circuits using hardware description languages (such as Verilog HDL or VHDL) or other suitable programming languages, such as various logic blocks, modules and circuits in integrated circuits.

In terms of software and/or firmware, the relevant functions of the controller 110 may be implemented as programming codes. For example, the controller 110 may be implemented using general programming languages (e.g., C, C++, or assembly languages) or other suitable programming languages. The programming code may be recorded/stored in a “non-transitory machine-readable storage medium”. In some embodiments, the non-transitory machine-readable storage medium includes, for example, a semiconductor memory and/or a storage device. The semiconductor memory includes a memory card, a read only memory (ROM), a FLASH memory, a programmable logic circuit or other semiconductor memories. The storage device includes a tape, a disk, a hard disk drive (HDD), a solid-state drive (SSD) or other storage devices. An electronic device (such as a computer, a CPU, a controller, a microcontroller or a microprocessor) may read and execute the programming codes from the non-transitory machine-readable storage medium, thereby realizing the relevant functions of the controller 110.

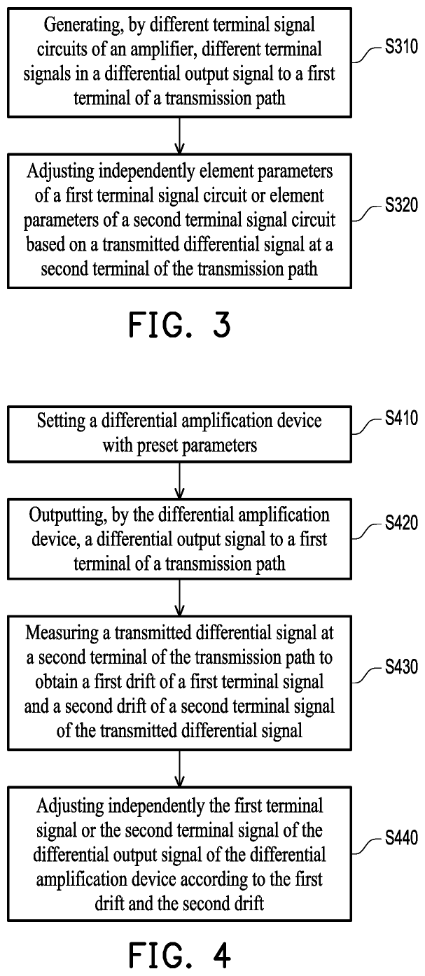

FIG. 3 is a schematic flowchart of a compensation method according to an embodiment of the disclosure. The compensation method shown in FIG. 3 may compensate for the asymmetric influence by the transmission path on the terminal signals RXp and RXn in the transmitted differential signal. Please refer to FIG. 2 and FIG. 3. In step S310, the different terminal signal circuits of the amplifier 120 generate the different terminal signals TXp and TXn in the differential output signal DSout to the first terminal of the transmission path. Specifically, the terminal signal circuit 121 may generate the terminal signal TXp in the differential output signal DSout to the first terminal of the transmission path, and the terminal signal circuit 122 may generate the terminal signal TXn in the differential output signal DSout to the first terminal of the transmission path.

The controller 110 is coupled to the terminal signal circuit 121 and the terminal signal circuit 122. In step S320, the controller 110 may independently adjust one or more element parameters of the terminal signal circuit 121, or independently adjust one or more element parameters of the terminal signal circuit 122 based on the transmitted differential signal (the terminal signals RXp and RXn) at a second terminal of the transmission path. That is, the adjustment of the element parameters of the terminal signal circuit 121 by the controller 110 may be independent of the adjustment of the element parameters of the terminal signal circuit 122. Based on this, the adjustment of the terminal signal TXp may be independent of the adjustment of the terminal signal TXn to compensate for the asymmetric influence by the transmission path on the terminal signals RXp and RXn in the transmitted differential signal. For example, in response to the attenuation of the terminal signal RXp by the transmission path being greater than the attenuation of the terminal signal RXn of the transmitted differential signal by the transmission path, the differential amplification device AMP21 may increase the voltage level of the terminal signal TXp without adjusting the voltage level of the terminal signal TXn, or the differential amplification device AMP21 may lower the voltage level of the terminal signal TXn without adjusting the voltage level of the terminal signal TXp. Therefore, the differential amplification device AMP21 may compensate for the asymmetric influence by the transmission path on the terminal signals RXp and/or RXn of the transmitted differential signal. For another example, in response to the attenuation of the terminal signal RXp of the transmitted differential signal by the transmission path being less than the attenuation of the terminal signal RXn of the transmitted differential signal by the transmission path, the differential amplification device AMP21 may lower the voltage level of the terminal signal TXp without adjusting the voltage level of the terminal signal TXn, or the differential amplification device AMP21 may increase the voltage level of the terminal signal TXn without adjusting the voltage level of the terminal signal TXp. Because the adjustment of the terminal signal TXp may be independent of the adjustment of the terminal signal TXn, the differential amplification device AMP21 may compensate for the asymmetric influence by the transmission path on the transmitted differential signal. Therefore, the differential amplification device AMP21 may compensate for the common mode voltage at the transmission terminal of the USB4 high-speed circuit, thereby complying with the requirements of the USB4 specification.

FIG. 4 is a schematic flowchart of a compensation method according to another embodiment of the disclosure. In step S410, the controller 110 sets the terminal signal circuits 121 and 122 of the differential amplification device AMP21 with preset parameters so that the terminal signal TXp or TXn of the differential output signal DSout is symmetrical to the rated common mode voltage level (for example, 0 V or other target levels, as determined by actual design). In step S420, the amplifier 120 of the differential amplification device AMP21 outputs the differential output signal DSout to the first terminal of the transmission path. In step S430, measuring equipment (not shown) measures the transmitted differential signal (the terminal signals RXp and RXn) at the second terminal of the transmission path to obtain a first drift of the terminal signal RXp and a second drift of the terminal signal RXn of the transmitted differential signal. In step S440, the controller 110 independently adjusts the terminal signal TXp or TXn of the differential output signal DSout of the differential amplification device AMP21 according to the first drift and the second drift. For example, when the attenuation of the terminal signal RXp by the transmission path is greater than the attenuation of the terminal signal RXn by the transmission path, the controller 110 may increase the voltage level of the terminal signal TXp without adjusting the voltage level of the terminal signal TXn, or the controller 110 may lower the voltage level of the terminal signal TXn without adjusting the voltage level of the terminal signal TXp.

In summary, the controller 110 may adjust the element parameters of the terminal signal circuit 121 independently of the adjustment of the element parameters of the terminal signal circuit 122. That is, the controller 110 may adjust the terminal signal TXp in the differential output signal DSout independently of the adjustment of the terminal signal TXn in the differential output signal DSout. Generally speaking, the transmission path may have the asymmetric influence on the transmitted differential signal (the terminal signals RXp and RXn). For example, the attenuation degree of the terminal signal RXp by the transmission path is different from the attenuation degree of the terminal signal RXn by the transmission path. Due to the asymmetric influence by the transmission path on the terminal signals RXp and RXn, the common mode voltages of the terminal signals RXp and RXn received by the receiving device may be far away from the rated common mode voltage level (such as 0 V or other target levels). Based on the transmitted differential signal (the terminal signals RXp and RXn) of the transmission path, the controller 110 may accordingly adjust/set the element parameters of the terminal signal circuit 121 and/or the element parameters of the terminal signal circuit 122. Because the adjustment of the element parameters of the terminal signal circuit 121 may be independent of the adjustment of the element parameters of the terminal signal circuit 122, the differential amplification device AMP21 may compensate for the asymmetric influence by the transmission path on the terminal signals RXp and RXn of the transmitted differential signal.

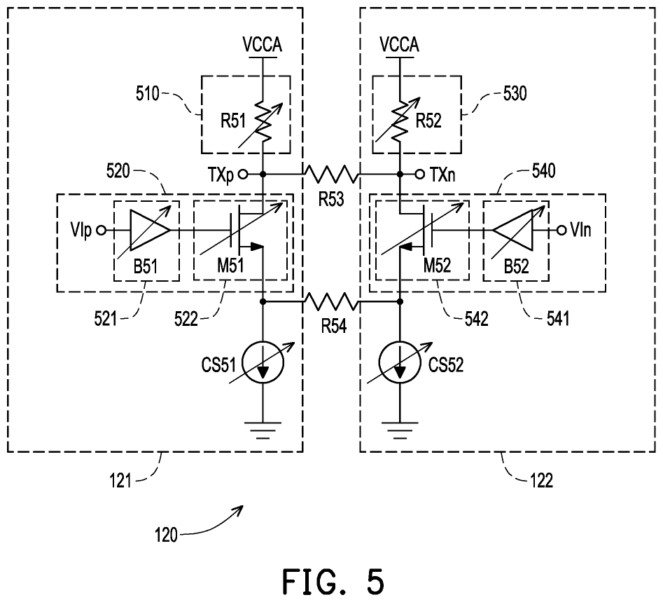

FIG. 5 is a schematic circuit block diagram of the amplifier 120 according to an embodiment of the disclosure. In the embodiment shown in FIG. 5, the terminal signal circuit 121 of the amplifier 120 includes a load circuit 510, an amplification circuit 520 and a current source CS51. A first terminal of the load circuit 510 is coupled to a voltage VCCA. A level of the voltage VCCA may be determined according to actual design. A second terminal of the load circuit 510 is coupled to an output terminal of the terminal signal circuit 121 to provide the terminal signal TXp in the differential output signal DSout. An input terminal of the amplification circuit 520 receives the terminal signal VIp in the differential input signal DSin. A first current terminal of the amplification circuit 520 is coupled to the second terminal of the load circuit 510. The current source CS51 is coupled to a second current terminal of the amplification circuit 520. The controller 110 may adjust/set one or more element parameters of the terminal signal circuit 121, and the element parameters include impedance of the load circuit 510, a gain of the amplification circuit 520, or a current value of the current source CS51.

In the embodiment shown in FIG. 5, the terminal signal circuit 122 includes a load circuit 530, an amplification circuit 540 and a current source CS52. A first terminal of the load circuit 530 is coupled to a voltage VCCA. A second terminal of the load circuit 530 is coupled to an output terminal of the terminal signal circuit 122 to provide the terminal signal TXn in the differential output signal DSout. An input terminal of the amplification circuit 540 receives the terminal signal VIn in the differential input signal DSin. A first current terminal of the amplification circuit 540 is coupled to the second terminal of the load circuit 530. The current source CS52 is coupled to a second current terminal of the amplification circuit 540. The controller 110 may adjust/set one or more element parameters of the terminal signal circuit 122, and the element parameters include impedance of the load circuit 530, a gain of the amplification circuit 540, or a current value of the current source CS52.

The second current terminal of the amplification circuit 520 of the terminal signal circuit 121 is coupled to the second current terminal of the amplification circuit 540 of the terminal signal circuit 122, and the output terminal of the terminal signal circuit 121 is coupled to the output terminal of the terminal signal circuit 122. In the embodiment shown in FIG. 5, the amplifier 120 further includes resistors R53 and R54. A first terminal of the resistor R53 is coupled to the output terminal of the terminal signal circuit 121. A second terminal of the resistor R53 is coupled to the output terminal of the terminal signal circuit 122. A first terminal of the resistor R54 is coupled to the second current terminal of the amplification circuit 520. A second terminal of the resistor R54 is coupled to the second current terminal of the amplification circuit 540.

In the embodiment shown in FIG. 5, the load circuit 510 includes a variable resistor R51, and the amplification circuit 520 includes a pushing unit 521 and an amplification unit 522. The variable resistor R51 is controlled by the controller 110. A first terminal of the variable resistor R51 is coupled to the voltage VCCA. A second terminal of the variable resistor R51 is coupled to the output terminal of the terminal signal circuit 121. A first current terminal of the amplification unit 522 is coupled to the second terminal of the load circuit 510. A second current terminal of the amplification unit 522 is coupled to the current source CS51. An output terminal of the pushing unit 521 is coupled to a control terminal of the amplification unit 522. An input terminal of the pushing unit 521 receives the terminal signal VIp in the differential input signal DSin.

In the embodiment shown in FIG. 5, the pushing unit 521 includes a buffer B51, and the amplification unit 522 includes a transistor M51. An input terminal of the buffer B51 receives the terminal signal VIp in the differential input signal DSin. An output terminal of the buffer B51 is coupled to the control terminal of the amplification unit 522. The controller 110 may control the gain of the buffer B51. A first terminal (e.g., drain) of the transistor M51 is coupled to the second terminal of the load circuit 510. A second terminal (e.g., source) of the transistor M51 is coupled to the current source CS51. A control terminal (e.g., gate) of the transistor M51 is coupled to the output terminal of the pushing unit 521. The controller 110 may control a channel width to length ratio (W/L) of the transistor M51. In order to increase the voltage level of the terminal signal TXp in the differential output signal DSout, the controller 110 may reduce the current value of the current source CS51, and/or reduce the channel width to length ratio of the transistor M51, and/or reduce the resistance value of the variable resistor R51, and/or reduce the gain of the buffer B51.

In response to the attenuation of the terminal signal RXp of the transmitted differential signal by the transmission path being greater than the attenuation of the terminal signal RXn of the transmitted differential signal by the transmission path, the controller 110 may reduce the current value of the current source CS51 (hereinafter referred to as a first current value), and/or reduce the gain of the amplification circuit 520 (hereinafter referred to as a first gain), and/or reduce the impedance of the load circuit 510 (hereinafter referred to as first impedance), and/or reduce the first current value and the first gain, and/or reduce the first gain and the first impedance, and/or reduce the first current value, the first gain and the first impedance. Based on this, without adjusting the terminal signal TXn in the differential output signal DSout, the controller 110 may increase the voltage level of the terminal signal TXp in the differential output signal DSout to compensate for the asymmetric influence by the transmission path on the terminal signals RXp and RXn of the transmitted differential signal.

In the embodiment shown in FIG. 5, the load circuit 530 includes a variable resistor R52, and the amplification circuit 540 includes a pushing unit 541 and an amplification unit 542. The variable resistor R52 is controlled by the controller 110. A first terminal of the variable resistor R52 is coupled to the voltage VCCA. A second terminal of the variable resistor R52 is coupled to the output terminal of the terminal signal circuit 122. A first current terminal of the amplification unit 542 is coupled to the second terminal of the load circuit 530. A second current terminal of the amplification unit 542 is coupled to the current source CS52. An output terminal of the pushing unit 541 is coupled to a control terminal of the amplification unit 542. An input terminal of the pushing unit 541 receives the terminal signal VIn in the differential input signal DSin.

In the embodiment shown in FIG. 5, the pushing unit 541 includes a buffer B52, and the amplification unit 542 includes a transistor M52. An input terminal of the buffer B52 receives the terminal signal VIn in the differential input signal DSin. An output terminal of the buffer B52 is coupled to the control terminal of the amplification unit 542. The controller 110 may control the gain of the buffer B52. A first terminal (e.g., drain) of the transistor M52 is coupled to the second terminal of the load circuit 530. A second terminal (e.g., source) of the transistor M52 is coupled to the current source CS52. A control terminal (e.g., gate) of the transistor M52 is coupled to the output terminal of the pushing unit 541. The controller 110 may control a channel width to length ratio (W/L) of the transistor M52. In order to increase the voltage level of the terminal signal TXn in the differential output signal DSout, the controller 110 may reduce the current value of the current source CS52, and/or reduce the channel width to length ratio of the transistor M52, and/or reduce the resistance value of the variable resistor R52, and/or reduce the gain of the buffer B52.

In response to the attenuation of the terminal signal RXp of the transmitted differential signal by the transmission path being less than the attenuation of the terminal signal RXn of the transmitted differential signal by the transmission path, the controller 110 may reduce the current value of the current source CS52 (hereinafter referred to as a second current value), and/or reduce the gain of the amplification circuit 540 (hereinafter referred to as a second gain), and/or reduce the impedance of the load circuit 530 (hereinafter referred to as second impedance), and/or reduce the second current value and the second gain, and/or reduce the second gain and the second impedance, and/or reduce the second current value, the second gain and the second impedance. Based on this, without adjusting the terminal signal TXp in the differential output signal DSout, the controller 110 may increase the voltage level of the terminal signal TXn in the differential output signal DSout to compensate for the asymmetric influence by the transmission path on the terminal signals RXp and RXn of the transmitted differential signal.

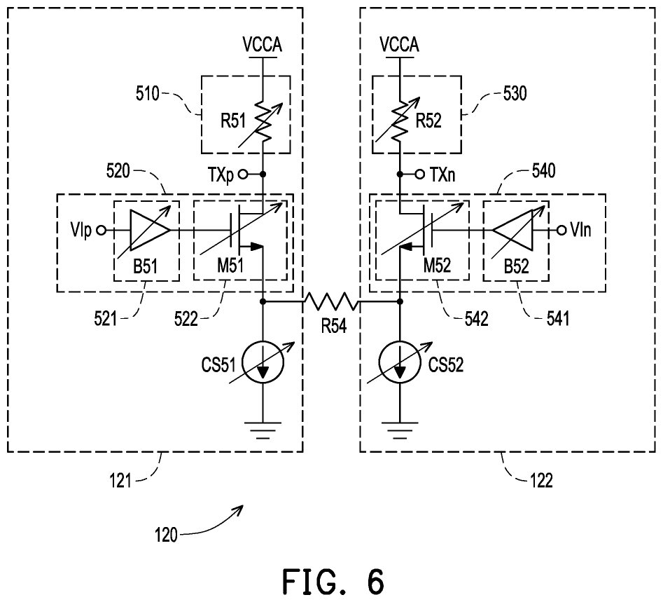

FIG. 6 is a schematic circuit block diagram of the amplifier 120 according to another embodiment of the disclosure. For the amplifier 120, the terminal signal circuit 121 and the terminal signal circuit 122 shown in FIG. 6, reference may be made to the relevant descriptions of the amplifier 120, the terminal signal circuit 121 and the terminal signal circuit 122 shown in FIG. 5, so the descriptions are not repeated here. Differences from the amplifier 120 shown in FIG. 5 include that the amplifier 120 shown in FIG. 6 omits the resistor R53.

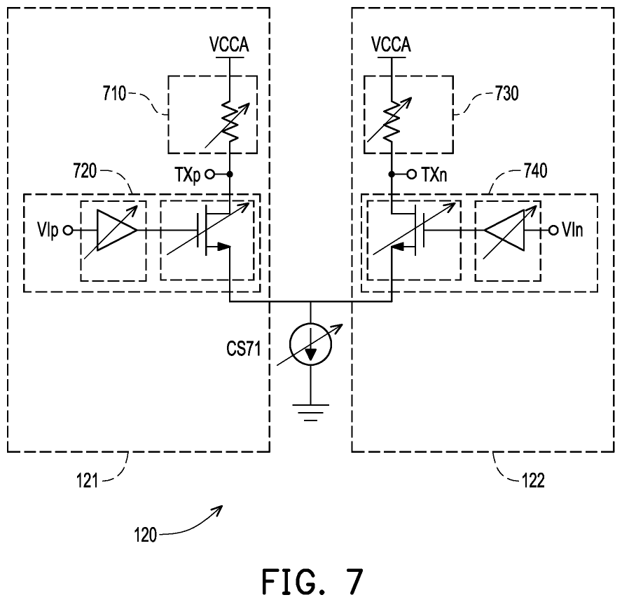

FIG. 7 is a schematic circuit block diagram of the amplifier 120 according to yet another embodiment of the disclosure. The terminal signal circuit 121 of the amplifier 120 shown in FIG. 7 includes a load circuit 710 and an amplification circuit 720, and the terminal signal circuit 122 includes a load circuit 730 and an amplification circuit 740. For the load circuit 710 and the amplification circuit 720 shown in FIG. 7, reference may be made to the relevant descriptions of the load circuit 510 and the amplification circuit 520 shown in FIG. 5, and for the load circuit 730 and the amplification circuit 740 shown in FIG. 7, reference may be made to the relevant descriptions of the load circuit 530 and the amplification circuit 540 shown in FIG. 5, so the descriptions are not repeated here. In the embodiment shown in FIG. 7, the amplifier 120 further includes a current source CS71. The current source CS71 is coupled to a second current terminal of the amplification circuit 720 of the terminal signal circuit 121 and a second current terminal of the amplification circuit 740 of the terminal signal circuit 122.

In the embodiment shown in FIG. 7, the controller 110 may adjust/set one or more element parameters of the terminal signal circuit 121, and/or adjust/set one or more element parameters of the terminal signal circuit 122. The element parameters of the terminal signal circuit 121 include impedance of the load circuit 710 and/or a gain of the amplification circuit 720, and the element parameters of the terminal signal circuit 122 include impedance of the load circuit 730 and/or a gain of the amplification circuit 740.

In response to the attenuation of the terminal signal RXp of the transmitted differential signal by the transmission path being greater than the attenuation of the terminal signal RXn of the transmitted differential signal by the transmission path, the controller 110 may reduce the gain of the amplification circuit 720 (hereinafter referred to as a first gain), and/or reduce the impedance of the load circuit 710 (hereinafter referred to as a first impedance), and/or reduce the first gain and the first impedance. Based on this, without adjusting the terminal signal TXn in the differential output signal DSout, the controller 110 may increase the voltage level of the terminal signal TXp in the differential output signal DSout to compensate for the asymmetric influence by the transmission path on the terminal signals RXp and RXn of the transmitted differential signal.

In response to the attenuation of the terminal signal RXp of the transmitted differential signal by the transmission path being less than the attenuation of the terminal signal RXn of the transmitted differential signal by the transmission path, the controller 110 may reduce the gain of the amplification circuit 740 (hereinafter referred to as a second gain), and/or reduce the impedance of the load circuit 730 (hereinafter referred to as a second impedance), and/or reduce the second gain and the second impedance. Based on this, without adjusting the terminal signal TXp in the differential output signal DSout, the controller 110 may increase the voltage level of the terminal signal TXn in the differential output signal DSout to compensate for the asymmetric influence by the transmission path on the terminal signals RXp and RXn of the transmitted differential signal.

To sum up, by independently adjusting the element parameters of the terminal signal circuit 121 or 122 through the controller 110, the differential amplification device AMP21 May compensate for the differences in the common mode voltage caused by the non-ideal effects of the transmission path on the positive and negative terminal signals of the differential signal, thereby reducing common-mode noise to comply with the requirements of the USB4 specification.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A differential amplification device, configured to generate a differential output signal to a first terminal of a transmission path, the differential amplification device comprising:
a first terminal signal circuit, configured to generate a first terminal signal in the differential output signal;
a second terminal signal circuit, coupled to the first terminal signal circuit, wherein the second terminal signal circuit generates a second terminal signal in the differential output signal; and
a controller, coupled to the first terminal signal circuit and the second terminal signal circuit, wherein the controller adjusts at least one first element parameter of the first terminal signal circuit or at least one second element parameter of the second terminal signal circuit based on a transmitted differential signal at a second terminal of the transmission path, so as to compensate for asymmetric influence by the transmission path on a first terminal signal and a second terminal signal in the transmitted differential signal, wherein adjustment of the at least one first element parameter of the first terminal signal circuit is independent of adjustment of the at least one second element parameter of the second terminal signal circuit.

2. The differential amplification device according to claim 1, wherein the first terminal signal circuit comprises:
a load circuit, having a first terminal coupled to a first voltage, wherein a second terminal of the load circuit is coupled to an output terminal of the first terminal signal circuit, and the output terminal provides the first terminal signal;
an amplification circuit, having an input terminal configured to receive a first terminal signal in a differential input signal of the differential amplification device, wherein a first current terminal of the amplification circuit is coupled to the second terminal of the load circuit; and
a current source, coupled to a second current terminal of the amplification circuit,
wherein the at least one first element parameter comprises impedance of the load circuit, a gain of the amplification circuit, or a current value of the current source.

3. The differential amplification device according to claim 2, wherein the load circuit comprises:
a variable resistor, controlled by the controller, wherein a first terminal of the variable resistor is coupled to the first voltage, and a second terminal of the variable resistor is coupled to an output terminal of the first terminal signal circuit.

4. The differential amplification device according to claim 2, wherein the amplification circuit comprises:
an amplification unit, wherein a first current terminal of the amplification unit is coupled to the second terminal of the load circuit, and a second current terminal of the amplification unit is coupled to the current source; and
a pushing unit, having an output terminal coupled to a control terminal of the amplification unit, wherein an input terminal of the pushing unit is configured to receive the first terminal signal in the differential input signal.

5. The differential amplification device according to claim 4, wherein the amplification unit comprises:
a transistor, wherein a first terminal of the transistor is coupled to the second terminal of the load circuit, a second terminal of the transistor is coupled to the current source, a control terminal of the transistor is coupled to the output terminal of the pushing unit and the controller controls a channel width to length ratio of the transistor.

6. The differential amplification device according to claim 4, wherein the pushing unit comprises:
a buffer, wherein an output terminal of the buffer is coupled to the control terminal of the amplification unit, an input terminal of the buffer is configured to receive the first terminal signal in the differential input signal and the controller controls a gain of the buffer.

7. The differential amplification device according to claim 2, wherein the second current terminal of the amplification circuit of the first terminal signal circuit is coupled to a second current terminal of an amplification circuit of the second terminal signal circuit.

8. The differential amplification device according to claim 7, further comprising:
a resistor, wherein a first terminal of the resistor is coupled to the second current terminal of the amplification circuit of the first terminal signal circuit, and a second terminal of the resistor is coupled to the second current terminal of the amplification circuit of the second terminal signal circuit.

9. The differential amplification device according to claim 1, further comprising:
a resistor, wherein a first terminal of the resistor is coupled to a first output terminal of the first terminal signal circuit, and a second terminal of the resistor is coupled to a second output terminal of the second terminal signal circuit.

10. The differential amplification device according to claim 1, wherein
in response to attenuation of the first terminal signal of the transmitted differential signal by the transmission path being greater than attenuation of the second terminal signal of the transmitted differential signal by the transmission path, the controller reduces a first current value of a first current source of the first terminal signal circuit, or the controller reduces a first gain of a first amplification circuit of the first terminal signal circuit, or the controller reduces first impedance of a first load circuit of the first terminal signal circuit, or the controller reduces the first current value and the first gain, or the controller reduces the first gain and the first impedance, or the controller reduces the first current value, the first gain and the first impedance; and
in response to the attenuation of the first terminal signal of the transmitted differential signal by the transmission path being less than the attenuation of the second terminal signal of the transmitted differential signal by the transmission path, the controller reduces a second current value of a second current source of the second terminal signal circuit, or the controller reduces a second gain of a second amplification circuit of the second terminal signal circuit, or the controller reduces second impedance of a second load circuit of the second terminal signal circuit, or the controller reduces the second current value and the second gain, or the controller reduces the second gain and the second impedance, or the controller reduces the second current value, the second gain and the second impedance.

11. The differential amplification device according to claim 1, wherein the first terminal signal circuit comprises:
a load circuit, having a first terminal coupled to a first voltage, wherein a second terminal of the load circuit is coupled to an output terminal of the first terminal signal circuit, and the output terminal provides the first terminal signal; and
an amplification circuit, having an input terminal configured to receive a first terminal signal in a differential input signal of the differential amplification device, wherein a first current terminal of the amplification circuit is coupled to the second terminal of the load circuit,
wherein the at least one first element parameter comprises impedance of the load circuit or a gain of the amplification circuit.

12. The differential amplification device according to claim 11, further comprising:
a current source, coupled to a second current terminal of the amplification circuit of the first terminal signal circuit and a second current terminal of an amplification circuit of the second terminal signal circuit.

13. A compensation method, configured to compensate for asymmetric influence by a transmission path on a first terminal signal and a second terminal signal in a transmitted differential signal, the compensation method comprising:
generating, by a first terminal signal circuit, a first terminal signal in a differential output signal to a first terminal of the transmission path;
generating, by a second terminal signal circuit, a second terminal signal in the differential output signal to the first terminal of the transmission path, wherein the second terminal signal circuit is coupled to the first terminal signal circuit; and
adjusting at least one first element parameter of the first terminal signal circuit or at least one second element parameter of the second terminal signal circuit based on the transmitted differential signal at a second terminal of the transmission path to compensate for the asymmetric influence by the transmission path on the first terminal signal and the second terminal signal of the transmitted differential signal, wherein adjustment of the at least one first element parameter of the first terminal signal circuit is independent of adjustment of the at least one second element parameter of the second terminal signal circuit.

14. The compensation method according to claim 13, wherein the first terminal signal circuit comprises a load circuit, an amplification circuit and a current source, a first terminal of the load circuit is coupled to a first voltage, a second terminal of the load circuit is coupled to an output terminal of the first terminal signal circuit, the output terminal provides the first terminal signal, an input terminal of the amplification circuit is configured to receive a first terminal signal in a differential input signal of the differential amplification device, a first current terminal of the amplification circuit is coupled to the second terminal of the load circuit, the current source is coupled to a second current terminal of the amplification circuit, and the at least one first element parameter comprises impedance of the load circuit, a gain of the amplification circuit or a current value of the current source.

15. The compensation method according to claim 13, further comprising:
in response to attenuation of the first terminal signal of the transmitted differential signal by the transmission path being greater than attenuation of the second terminal signal of the transmitted differential signal by the transmission path, reducing a first current value of a first current source of the first terminal signal circuit, or reducing a first gain of a first amplification circuit of the first terminal signal circuit, or reducing first impedance of a first load circuit of the first terminal signal circuit, or reducing the first current value and the first gain, or reducing the first gain and the first impedance, or reducing the first current value, the first gain and the first impedance; and
in response to the attenuation of the first terminal signal of the transmitted differential signal by the transmission path being less than the attenuation of the second terminal signal of the transmitted differential signal by the transmission path, reducing a second current value of a second current sources of the second terminal signal circuit, or reducing a second gain of a second amplification circuit of the second terminal signal circuit, or reducing second impedance of a second load circuit of the second terminal signal circuit, or reducing the second current value and the second gain, or reducing the second gain and the second impedance, or reducing the second current value, the second gain and the second impedance.

16. The compensation method according to claim 13, wherein the first terminal signal circuit comprises a load circuit and an amplification circuit, a first terminal of the load circuit is coupled to a first voltage, a second terminal of the load circuit is coupled to an output terminal of the first terminal signal circuit, the output terminal provides the first terminal signal, an input terminal of the amplification circuit is configured to receive a first terminal signal in a differential input signal of the differential amplification device, a first current terminal of the amplification circuit is coupled to the second terminal of the load circuit, and the at least one first element parameter comprises impedance of the load circuit or a gain of the amplification circuit.
